(19) United States
(12) Patent Application Publication
(10) Pub. No.: US 2026/0371598 A1
(43) Pub. Date: Nov. 19, 2026

(54) ELECTROCHEMICAL MEMORY DEVICE, ELECTRONIC DEVICE INCLUDING THE SAME, AND METHOD OF MANUFACTURING THE ELECTROCHEMICAL MEMORY DEVICE

(71) Applicant: Samsung Electronics Co., Ltd., Suwon-si (KR)

(72) Inventors: Moonil JUNG, Suwon-si (KR); Sunho KIM, Suwon-si (KR); Seungdam HYUN, Suwon-si (KR)

(73) Assignee: Samsung Electronics Co., Ltd., Suwon-si (KR)

(21) Appl. No.: 19/646,999

(22) Filed: Apr. 14, 2026

(30) Foreign Application Priority Data
May 14, 2025 (KR) 10-2025-0062823

(51) Int. Cl. H10B 43/35; H10B 43/10; H10B 43/27; H10D 30/01; H10D 30/69; H10D 62/80; H10D 64/68

(52) U.S. Cl. CPC H10B 43/35; H10B 43/10; H10B 43/27; H10D 30/693; H10D 62/875; H10D 64/685; H10D 64/691; H10D 30/0413

(57) ABSTRACT

Provided are an electrochemical memory device, an electronic device including the electrochemical memory device, and a method of manufacturing the electrochemical memory device. The electrochemical memory device may include a substrate, a plurality of isolation layers and a plurality of gate electrodes alternately stacked in a first direction perpendicular to a surface of the substrate, a channel hole penetrating the plurality of isolation layers and the plurality of gate electrodes in the first direction, an oxygen reservoir layer in the channel hole and configured to store at least one of oxygen ions and oxygen vacancies, an oxide semiconductor layer on an inner side of the oxygen reservoir layer, and an oxygen getter layer on an inner side of the oxide semiconductor layer and configured to generate oxygen vacancies in the oxide semiconductor layer.

### CROSS-REFERENCE TO RELATED APPLICATION

This application is based on and claims priority under 35 U.S.C. § 119 to Korean Patent Application No. 10-2025-0062823, filed on May 14, 2025 in the Korean Intellectual Property Office, the disclosure of which is incorporated by reference herein in its entirety.

### BACKGROUND

### 1. Field

The disclosure relates to an electrochemical memory device, an electronic device including the electrochemical memory device, and/or a method of manufacturing the electrochemical memory device.

### 2. Description of the Related Art

Along with the replacement of hard disk drives with solid state drives (SSDs), NAND flash memory devices, which are nonvolatile memory devices, have been widely used. The miniaturization and high integration of nonvolatile memory devices have led to the development of vertical NAND (VNAND) flash memory devices in which a plurality of memory cells are stacked in a direction perpendicular to a substrate.

As demands for high integration and low power consumption continue to grow, there has been increasing interest in addressing issues such as high program/erase voltage, narrow memory window, and data retention.

### SUMMARY

Provided are an electrochemical memory device capable of changing the electrical conductivity of a channel layer by using ions, an electronic device including the electrochemical memory device, and a method of manufacturing the electrochemical memory device.

Provided are an electrochemical memory device capable of more easily changing the electrical conductivity of a channel layer, an electronic device including the electrochemical memory device, and a method of manufacturing the electrochemical memory device.

Additional aspects will be set forth in part in the description which follows and, in part, will be apparent from the description, or may be learned by practice of the presented embodiments of the disclosure.

According to an aspect of the disclosure, an electrochemical memory device may include a substrate, a plurality of isolation layers and a plurality of gate electrodes alternately stacked in a first direction on a surface of the substrate, the first direction being perpendicular to the surface of the substrate, the plurality of isolation layers and the plurality of gate electrodes defining a channel hole penetrating the plurality of isolation layers and the plurality of gate electrodes in the first direction; an oxygen reservoir layer in the channel hole and configured to store at least one of oxygen ions and oxygen vacancies; an oxide semiconductor layer on an inner side of the oxygen reservoir layer; and an oxygen getter layer on an inner side of the oxide semiconductor layer and configured to generate oxygen vacancies in the oxide semiconductor layer.

In some embodiments, the oxygen getter layer may be insulative.

In some embodiments, the oxygen getter layer may include a first metal, the oxide semiconductor layer may include a second metal that is different from the first metal, and the first metal may have a lower oxide formation energy than the second metal.

In some embodiments, the oxide semiconductor layer may include the first metal, and a content of the first metal in the oxygen getter layer may be greater than a content of the first metal in the oxide semiconductor layer.

In some embodiments, a content of the first metal included in the oxide semiconductor layer may decrease from a region in contact with the oxygen getter layer to a region in contact with the oxygen reservoir layer.

In some embodiments, a content of the first metal in the oxide semiconductor layer may be less than a content of the second metal in the oxide semiconductor layer.

In some embodiments, a content of the second metal in the oxygen getter layer may be 0 at %.

In some embodiments, the oxygen getter layer may include a metal having an oxide formation energy of −900 kJ/mol or less at a pressure of 1 atm and a temperature of 0 °C to 400 °C.

In some embodiments, the oxygen getter layer may include at least one selected from aluminum (Al), magnesium (Mg), and calcium (Ca).

In some embodiments, the oxygen getter layer may may have a thickness of 1 nm or less.

In some embodiments, the oxide semiconductor layer may include an oxide including at least one selected from indium (In), gallium (Ga), tin (Sn), cadmium (Cd), germanium (Ge), hafnium (Hf), and zinc (Zn).

In some embodiments, the oxygen reservoir layer may include a metal oxide that does not satisfy a stoichiometric ratio.

In some embodiments, the oxygen reservoir layer may include at least one selected from molybdenum (Mo), gadolinium (Gd), tantalum (Ta), hafnium (Hf), aluminum (Al), zinc (Zn), tungsten (W), vanadium (V), titanium (Ti), niobium (Nb), germanium (Ge), arsenic (As), tellurium (Te), antimony (Sb), gallium (Ga), indium (In), zirconium (Zr), tin (Sn), and nickel (Ni).

In some embodiments, the oxide semiconductor layer may include a first oxide semiconductor layer between the oxygen reservoir layer and the oxygen getter layer and having a lower oxygen dissociation energy than the oxygen reservoir layer, and a second oxide semiconductor layer between the first oxide semiconductor layer and the oxygen getter layer and having a lower oxygen dissociation energy than the first oxide semiconductor layer.

In some embodiments, the electrochemical memory device may further include an electrolyte layer between the oxygen reservoir layer and the oxide semiconductor layer.

In some embodiments, the electrochemical memory device may further include a gate insulating layer between the oxygen reservoir layer and the plurality of gate electrodes.

In some embodiments, the oxide semiconductor layer may be doped with a halogen element.

According to another aspect of the disclosure, an electronic device may include a nonvolatile memory device, and a memory controller configured to control the nonvolatile memory device to read data from the nonvolatile memory device and/or program data to the nonvolatile memory device. The nonvolatile memory device may include a substrate; a plurality of isolation layers and a plurality of gate electrodes alternately stacked in a first direction on a surface of the substrate, the first direction being perpendicular to the surface of the substrate, the plurality of isolation layers and the plurality of gate electrodes defining a channel hole penetrating the plurality of isolation layers and the plurality of gate electrodes in the first direction; an oxygen reservoir layer in the channel hole and configured to store at least one of oxygen ions and oxygen vacancies; an oxide semiconductor layer on an inner side of the oxygen reservoir layer; and an oxygen getter layer on an inner side of the oxide semiconductor layer and configured to generate oxygen vacancies in the oxide semiconductor layer.

According to another aspect of the disclosure, a method of manufacturing an electrochemical memory device may include alternately forming a plurality of first insulating material layers and a plurality of second insulating material layers on a substrate, forming a channel hole that penetrates the plurality of first insulating material layers and the plurality of second insulating material layers in a first direction, sequentially forming an oxygen reservoir layer and an oxide semiconductor layer on an inner side of the channel hole, and forming an oxygen getter layer on an inner side of the oxide semiconductor layer by using oxygen included in the oxide semiconductor layer. The first direction may be perpendicular to the substrate.

In some embodiments, the oxygen getter layer may include at least one selected from aluminum (Al), magnesium (Mg), and calcium (Ca).

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view illustrating a schematic structure of an electrochemical memory device according to an embodiment;

FIG. 2 is a perspective view illustrating a schematic structure of a cell string included in the electrochemical memory device shown in FIG. 1;

FIG. 3 is a circuit diagram including the electrochemical memory device shown in FIG. 1, according to an embodiment;

FIG. 4 is a view illustrating oxygen vacancies when no operation voltage is applied to a selected memory cell, according to an embodiment;

FIG. 5 is a view illustrating oxygen ions and oxygen vacancies when a positive voltage is applied to a selected memory cell, according to an embodiment;

FIG. 6 is a view illustrating oxygen ions and oxygen vacancies when a negative voltage is applied to a selected memory cell, according to an embodiment;

FIG. 7 is a view illustrating a test memory device including an oxygen getter layer, according to an embodiment;

FIG. 8 is a graph illustrating current-voltage (IV) characteristics of a memory device according to a comparative example;

FIG. 9 is a graph illustrating IV characteristics of a memory device according to an embodiment.

FIG. 10 is a view illustrating an electrochemical memory device including a plurality of oxide semiconductor layers, according to an embodiment;

FIG. 11 is a view illustrating an electrochemical memory device including an electrolyte layer, according to an embodiment;

FIGS. 12A to 12H are reference views illustrating a method of manufacturing an electrochemical memory device according to an embodiment;

FIG. 13 is a schematic block diagram illustrating a display driver integrated circuit (display driver IC or DDI) and a display device including the DDI, according to an embodiment;

FIG. 14 is a block diagram illustrating an electronic device according to an embodiment;

FIG. 15 is a block diagram illustrating an electronic device according to an embodiment;

FIG. 16 is a conceptual view schematically illustrating a device architecture applicable to an electronic device, according to an embodiment; and

FIG. 17 is a conceptual view schematically illustrating a device architecture applicable to an electronic device, according to an embodiment.

### DETAILED DESCRIPTION

Reference will now be made in detail to embodiments, examples of which are illustrated in the accompanying drawings. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, an electrochemical memory device, an electronic device including the electrochemical memory device, and a method of manufacturing the electrochemical memory device will be described according to various embodiments with reference to the accompanying drawings. In the drawings, like reference numerals refer to like elements, and the sizes of elements may be exaggerated for clarity of illustration.

The terms of a singular form may include plural forms unless otherwise mentioned. It will be further understood that the terms “comprises” and/or “comprising” used herein specify the presence of stated features or elements, but do not preclude the presence or addition of one or more other features or elements. In the drawings, the sizes or thicknesses of elements may be exaggerated for clarity of illustration. In addition, when a material layer is referred to as being “above” or “on” a substrate or another layer, it may be directly on the substrate or the other layer while making contact with the substrate or the other layer or may be above the substrate or the other layer with a third layer therebetween. In the following descriptions of the embodiments, a material of each layer is merely an example, and another material may be used.

In the present disclosure, terms such as “unit” or “module” may be used to denote a unit that has at least one function or operation and is implemented with hardware, software, or a combination of hardware and software.

Specific executions described herein are merely examples and do not limit the scope of the present disclosure in any way. For simplicity of description, other functional aspects of conventional electronic configurations, control systems, software and the systems may be omitted.

Furthermore, line connections or connection members between elements depicted in the drawings represent functional connections and/or physical or circuit connections by way of example, and in actual applications, they may be replaced or embodied as various additional functional connections, physical connections, or circuit connections.

An element referred to with the definite article or a demonstrative determiner may be construed as the element or the elements even though it has a singular form.

Operations of a method may be performed in an appropriate order unless explicitly described in terms of order or described to the contrary. In addition, examples or terms (for example, “such as” and “etc.”) are used for the purpose of description and are not intended to limit the scope of the inventive concept unless defined by the claims.

Expressions such as “at least one” preceding a list of elements specify the entire list of elements and do not specify individual elements within the list. For example, expressions such as “at least one of A, B, and C” or “at least one selected from the group consisting of A, B, and C” may be interpreted as indicating only A, only B, only C, or any combination of two or more of A, B, and C such as ABC, AB, BC, and AC.

When terms such as “approximately” or “substantially” are used in relation to a numerical value, the numerical value may be interpreted as including manufacturing or operational variations from the numerical value (for example, a variation of ±10 %). Furthermore, when terms such as “generally” and “substantially” are used in relation to geometric shapes, geometric precision may not be required, and permissible variations of the geometric shapes may be within the scope of embodiments. In addition, regardless of whether numerical values or shapes are qualified or described by “approximately” or “substantially,” the numerical values or shapes may be interpreted as including manufacturing or operational variations from the numerical values or shapes (for example, a variation of ±10 %).

It will be understood that although terms such as “first” and “second” are used herein to describe various elements, these elements should not be limited by these terms. These terms are only used to distinguish one element from other elements.

Examples or terms are just used herein to describe technical ideas and should not be considered for purposes of limitation unless defined by the claims.

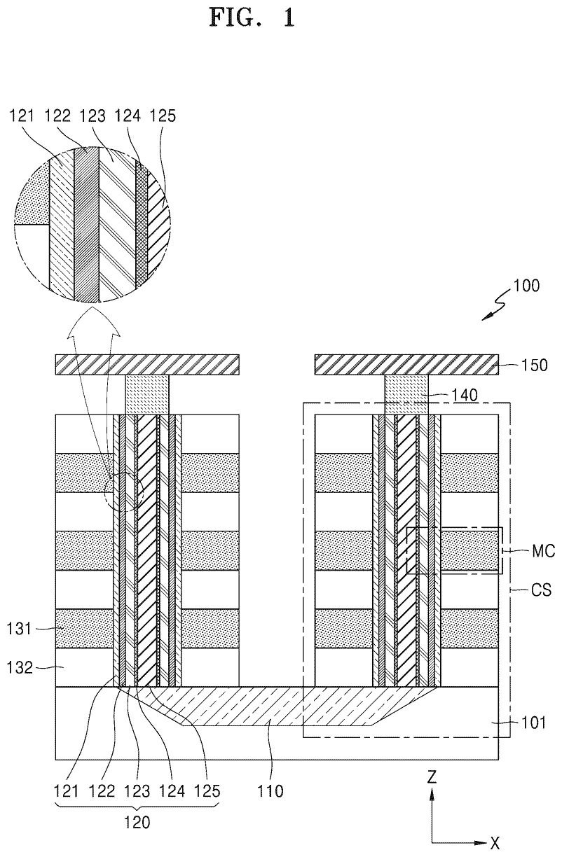

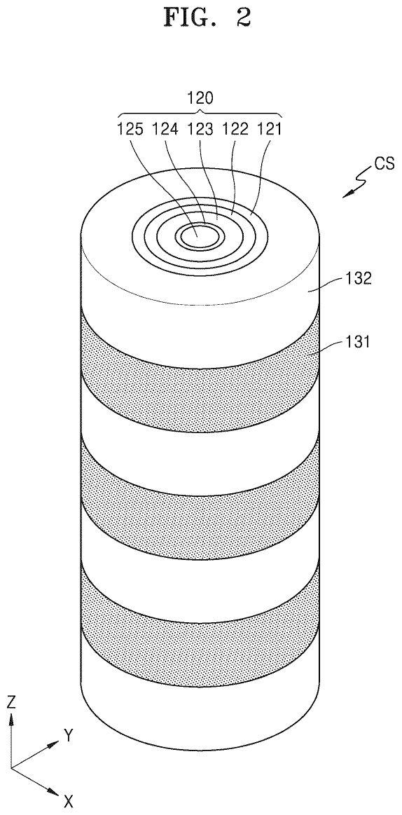

FIG. 1 is a cross-sectional view illustrating a schematic structure of an electrochemical memory device 100 according to an embodiment, and FIG. 2 is a perspective view illustrating a schematic structure of a cell string provided in the electrochemical memory device 100 shown in FIG. 1. According to an embodiment, the electrochemical memory device 100 may be, for example, a nonvolatile memory device. In an example, the nonvolatile memory device may be a flash memory device, a read-only memory (ROM) device, a hard disk, a diskette drive, magnetic tape, or an optical disk, but is not limited thereto. In an example, the nonvolatile memory device may be a flash memory device. In an example, the flash memory device may be a NAND flash memory device such as a vertical NAND (VNAND) flash memory device.

Referring to FIGS. 1 and 2, a plurality of cell strings CS are formed on a substrate 101. The substrate 101 may include a semiconductor doped with a dopant of a first type. For example, the substrate 101 may include a silicon material doped with a dopant of a first type. For example, the substrate 101 may include a silicon material doped with a p-type dopant. For example, the substrate 101 may be a p-type well (for example, a pocket p-well). Hereinafter, it is assumed that the substrate 101 may include p-type silicon. However, embodiments are not limited thereto. The substrate 101 may be a plastic substrate, a glass substrate, a compound semiconductor substrate, a ceramic substrate, or a silicon-on-insulator (SOI) substrate. In an example, the substrate 101 may include a periphery circuit for selecting and controlling electronic elements such as transistors or memory cells.

A common source region 110 is provided in the substrate 101. For example, the common source region 110 may be of a second type that is different from the type of the substrate 101. For example, the common source region 110 may be of an n-type. Hereinafter, it is assumed that the common source region 110 is of an n-type. However, the common source region 110 is not limited to being of an n-type and may be of a p-type.

Each of the cell strings CS may include a cylindrical channel hole 120 and a plurality of gate electrodes 131 and a plurality of isolation layers 132 that surround the channel hole 120. The gate electrodes 131 and the isolation layers 132 may be alternately stacked in a vertical direction (Z-axis direction). Because the gate electrodes 131 are stacked in a direction perpendicular to a surface of the substrate 101, the electrochemical memory device 100 shown in FIG. 1 may be referred to as a vertical memory device.

The gate electrodes 131 may include a metal material or a heavily doped silicon material. The gate electrodes 131 may include a highly conductive metal material, a metal nitride, silicon doped with a dopant, or the like. The gate electrodes 131 may include at least one selected from gold (Au), silver (Ag), aluminum (Al), titanium (Ti), indium (In), cadmium (Cd), copper (Cu), zinc (Zn), tantalum (Ta), molybdenum (Mo), and tungsten (W), but is not limited thereto.

The isolation layers 132 may each serve as a spacer for insulation between conductive layers. The isolation layers 132 may include various insulating materials such as silicon oxide or silicon nitride.

The channel hole 120 penetrates the gate electrodes 131 and the isolation layers 132. Here, the channel hole 120 may extend in the direction perpendicular to the surface of the substrate 101 (that is, the Z-axis direction in FIG. 2). The channel hole 120 may have a circular cross-section.

The channel hole 120 may be filled with a plurality of layers. A gate insulating layer 121 may be provided on an inner side of the channel hole 120, an oxygen reservoir layer 122 may be provided on an inner side of the gate insulating layer 121, an oxide semiconductor layer 123 may be provided on an inner side of the oxygen reservoir layer 122, an oxygen getter layer 124 may be provided on an inner side of the oxide semiconductor layer 123, and a pillar 125 may be provided on an inner side of the oxygen getter layer 124.

The gate insulating layer 121 may extend in the direction perpendicular to the surface of the substrate 101. The gate insulating layer 121 may have a cylindrical shape. The gate insulating layer 121 may be provided on an inner wall of the channel hole 120 and may be in contact with the gate electrodes 131 and the isolation layers 132. The gate insulating layer 121 may be conformally deposited in the channel hole 120.

The gate insulating layer 121 may include a metal oxide. For example, the gate insulating layer 121 may include an oxide including at least one metal element selected from tantalum (Ta), hafnium (Hf), aluminum (Al), zinc (Zn), tungsten (W), vanadium (V), titanium (Ti), niobium (Nb), germanium (Ge), arsenic (As), tellurium (Te), antimony (Sb), gallium (Ga), indium (In), zirconium (Zr), tin (Sn), and nickel (Ni), but is not limited thereto. In an example, the gate insulating layer 121 may include at least one selected from aluminum oxide and tin oxide.

The oxygen reservoir layer 122 may be provided on the inner side of the gate insulating layer 121. The oxygen reservoir layer 122 may extend in the direction perpendicular to the surface of the substrate 101. The oxygen reservoir layer 122 may have a cylindrical shape.

The oxygen reservoir layer 122 may include at least one selected from oxygen ions and oxygen vacancies. In an embodiment, the oxygen reservoir layer 122 may include a material with high ion storage capacity. The oxygen reservoir layer 122 may include a metal oxide. The oxygen dissociation energy of the oxygen reservoir layer 122 may be lower than the oxygen dissociation energy of the gate insulating layer 121. The term “oxygen dissociation energy” refers to the energy required for oxygen to separate from a metal in a bonded state, and the oxygen dissociation energy of a layer may refer to the average oxygen dissociation energy of at least one metal included in the layer.

The oxygen reservoir layer 122 may include an oxide including at least one selected from molybdenum (Mo), gadolinium (Gd), tantalum (Ta), hafnium (Hf), aluminum (Al), zinc (Zn), tungsten (W), vanadium (V), titanium (Ti), niobium (Nb), germanium (Ge), arsenic (As), tellurium (Te), antimony (Sb), gallium (Ga), indium (In), zirconium (Zr), tin (Sn), and nickel (Ni), but is not limited thereto. In an embodiment, the oxygen reservoir layer 122 may include hafnium oxide.

In an embodiment, the oxygen reservoir layer 122 may include a metal oxide that does not satisfy a stoichiometric ratio. That is, the bonding ratio of a metal and oxygen in the metal oxide may not satisfy a stoichiometric ratio. For example, when the stoichiometric ratio of a metal (Me) and oxygen (O) is Me:O=1:2, the oxygen reservoir layer 122 may include a metal oxide expressed by MeO₂₋ₓ(0<x<2). For example, the oxygen reservoir layer 122 may include HfO₂₋ₓ(0<x<2).

When the oxygen reservoir layer 122 has high ion storage capacity and insulating characteristics, the oxygen reservoir layer 122 may replace the gate insulating layer 121. That is, in an embodiment, the electrochemical memory device 100 may not include the gate insulating layer 121, and only the oxygen reservoir layer 122 may be provided between the oxide semiconductor layer 123 and the gate electrodes 131.

The oxide semiconductor layer 123 may be conformally provided along an inner wall of the oxygen reservoir layer 122. The oxide semiconductor layer 123 may serve as a channel layer in the electrochemical memory device 100.

In an embodiment, the oxide semiconductor layer 123 may include at least one metal. The oxygen dissociation energy of the at least one metal included in the oxide semiconductor layer 123 may be less than the oxygen dissociation energy of a metal included in the oxygen reservoir layer 122. Therefore, oxygen ions and oxygen vacancies may be more easily generated in the oxide semiconductor layer 123 than in the oxygen reservoir layer 122. Oxygen dissociation energy may vary with pressure and temperature. In an embodiment, under the pressure and temperature (for example, atmospheric pressure and room temperature) at which the electrochemical memory device 100 operates, the oxygen dissociation energy of the oxide semiconductor layer 123 may be less than the oxygen dissociation energy of the oxygen reservoir layer 122.

In an embodiment, the oxide semiconductor layer 123 may include an oxide including at least one selected from tantalum (Ta), hafnium (Hf), aluminum (Al), zinc (Zn), tungsten (W), vanadium (V), titanium (Ti), niobium (Nb), silicon (Si), germanium (Ge), arsenic (As), tellurium (Te), antimony (Sb), gallium (Ga), indium (In), zirconium (Zr), tin (Sn), and nickel (Ni).

For example, the oxide semiconductor layer 123 may include indium gallium zinc oxide (IGZO). The oxide semiconductor layer 123 may include indium (In), gallium (Ga), and zinc (Zn) in a ratio of 1:1:1. Alternatively, the oxide semiconductor layer 123 may include at least one selected from indium tungsten oxide (IWO), indium tin gallium oxide (ITGO), indium aluminum zinc oxide (IAGO), indium gallium oxide (IGO), indium tin zinc oxide (ITZO), zinc tin oxide (ZTO), indium zinc oxide (IZO), zinc oxide (ZnO), tungsten oxide (WO), indium gallium silicon oxide (IGSO), indium oxide (InO), tin oxide (SnO), titanium oxide (TiO), magnesium zinc oxide (MgZnO), indium zinc oxide (InZnO), indium gallium zinc oxide (InGaZnO), zirconium indium zinc oxide (ZrInZnO), hafnium indium zinc oxide (HfInZnO), tin indium zinc oxide (SnInZnO), aluminum tin indium zinc oxide (AlSnInZnO), silicon indium zinc oxide (SiInZnO), zinc tin oxide (ZnSnO), aluminum, zinc tin oxide (AlZnSnO), gallium zinc tin oxide (GaZnSnO), zirconium zinc tin oxide (ZrZnSnO), and indium gallium silicon oxide (InGaSiO).

In an embodiment, the oxide semiconductor layer 123 may further include a halogen element. For example, the halogen element may include at least one selected from fluorine (F), chlorine (Cl), bromine (Br), and iodine (I). For example, when the oxide semiconductor layer 123 includes fluorine (F), the content of fluorine (F) may be 2×10¹⁴/cm² or more. The halogen element may facilitate the movement of oxygen ions and also secure the thermal stability of the electrochemical memory device 100.

The oxygen getter layer 124 may be provided along an inner wall of the oxide semiconductor layer 123. The oxygen getter layer 124 may include a metal oxide. The oxygen getter layer 124 may include an insulative metal oxide. The oxygen getter layer 124 may include a metal that has a lower oxide formation energy than the at least one metal included in the oxide semiconductor layer 123. Here, the term “oxide formation energy” refers to the energy required to form a metal oxide through bonding between a metal and oxygen, and may vary with temperature and pressure. In an embodiment, the term “oxide formation energy” may refer to oxide formation energy at the time of manufacturing a memory device, for example, during formation of the oxygen getter layer 124 on the oxide semiconductor layer 123.

The oxygen getter layer 124 may include a metal that has an oxide formation energy of −900 kJ/mol or less at a pressure of about 1 atm and a temperature of about 0 °C to about 400 °C. For example, the oxygen getter layer 124 may include at least one selected from aluminum (Al), magnesium (Mg), and calcium (Ca).

When the oxide formation energy of the oxygen getter layer 124 is less than the oxide formation energy of the oxide semiconductor layer 123, the bonding between a metal and oxygen in the oxygen getter layer 124 may be easier than the bonding between a metal and oxygen in the oxide semiconductor layer 123. When the oxygen getter layer 124 is formed on the oxide semiconductor layer 123, oxygen contained in the oxide semiconductor layer 123 may move from the oxide semiconductor layer 123 and bond with a metal that is a source of the oxygen getter layer 124. Therefore, the oxygen getter layer 124 may be formed by obtaining oxygen from the oxide semiconductor layer 123, while the oxide semiconductor layer 123 may generate oxygen vacancies due to the release of oxygen. That is, when the oxygen getter layer 124 is formed, the oxygen getter layer 124 may generate oxygen vacancies in the oxide semiconductor layer 123. Because the oxide semiconductor layer 123 includes oxygen vacancies, the electrical conductivity of the oxide semiconductor layer 123 may be varied even with a low operation voltage.

From another perspective, when the oxygen getter layer 124 includes a first metal and the oxide semiconductor layer 123 includes a second metal different from the first metal, the oxide formation energy of the first metal may be less than the oxide formation energy of the second metal. The first metal may be any one of aluminum (Al), magnesium (Mg), and calcium (Ca), and the second metal may be any one of indium (In), gallium (Ga), tin (Sn), cadmium (Cd), germanium (Ge), hafnium (Hf), and zinc (Zn).

The oxide semiconductor layer 123 may also include the first metal. The content of the first metal included in the oxide semiconductor layer 123 may be less than the content of the first metal included in the oxygen getter layer 124. The content of the first metal included in the oxide semiconductor layer 123 may be less than the content of the second metal included in the oxide semiconductor layer 123. Alternatively, the content of the first metal included in the oxide semiconductor layer 123 may decrease from a region adjacent to the oxygen getter layer 124 toward a region adjacent to the oxygen reservoir layer 122. The first metal may be included in the oxide semiconductor layer 123 during the formation of the oxide semiconductor layer 123, or the first metal included in the oxygen getter layer 124 may diffuse into the oxide semiconductor layer 123 during a subsequent process of the electrochemical memory device 100. The oxygen getter layer 124 may also include the second metal, but the content of the second metal in the oxygen getter layer 124 may be extremely small or 0 at %.

The thickness (X-axis thickness) of the oxygen getter layer 124 may be less than the thickness (X-axis thickness) of the oxide semiconductor layer 123. As the oxygen getter layer 124 is formed to be thicker, more oxygen vacancies may be generated in the oxide semiconductor layer 123. When oxygen vacancies are excessively generated in the oxide semiconductor layer 123, the oxide semiconductor layer 123 may lose semiconductor characteristics. Therefore, the oxygen getter layer 124 may be formed to a thickness that allows the oxide semiconductor layer 123 to maintain semiconductor characteristics. For example, the thickness of the oxygen getter layer 124 may be about 1 nm or less, about 0.5 nm or less, or about 0.3 nm or less.

The pillar 125 may be provided inside the oxygen getter layer 124. The pillar 125 may include, for example, silicon oxide or air, but is not limited thereto.

The oxide semiconductor layer 123 may be in contact with a doped region, that is, the common source region 110.

A drain 140 may be provided above the channel hole 120. The drain 140 may include a silicon material doped with a dopant of the second type. For example, the drain 140 may include a silicon material doped with an n-type dopant.

A bit line 150 may be provided on the drain 140. The drain 140 and the bit line 150 may be connected to each other through contact plugs.

Each of the gate electrodes 131, and a region of the oxygen reservoir layer 122 and a region of the oxide semiconductor layer 123 that are horizontally arranged with the gate electrode 131 may form a memory cell MC. Such memory cells MC are continuously arranged in the vertical direction (Z-axis direction), thereby forming a cell string CS. The electrochemical memory device 100 has a structure in which cells are connected to each other in the vertical direction.

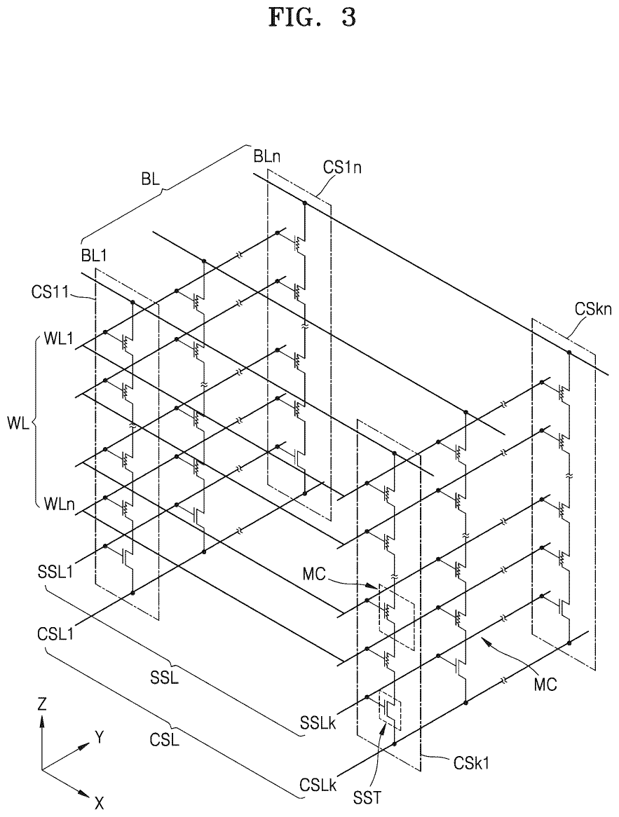

FIG. 3 illustrates a circuit diagram including the electrochemical memory device 100 shown in FIG. 1, according to an embodiment. k*n cell strings CS may be arranged in a matrix form and may be denoted with CSij (1≤i≤k, 1≤j≤n) based on row and column positions. Each of the cell strings CSij may be connected to a bit line BL, a string select line SSL, word lines WL, and a common source line CSL.

Each of the cell strings CSij may include memory cells MC and a string select transistor SST. The memory cells MC and the string select transistor SST of each of the cell strings CSij may be stacked in a vertical direction.

Rows of the cell strings CS are each connected to different string select lines SSL1 to SSLk. For example, the string select transistors SST of the cell strings CS11 to CS1n are commonly connected to the string select line SSL1. The string select transistors SST of the cell strings CSk1 to CSkn are commonly connected to the string select line SSLk.

Columns of the cell strings CS are connected to different bit lines BL1 to BLn. For example, the memory cells MC and the string select transistors SST of the cell strings CS11 to CSk1 may be commonly connected to the bit line BL1, and the memory cells MC and the string select transistors SST of the cell strings CS1n to CSkn may be commonly connected to the bit line BLn.

The rows of the cell strings CS may be connected to different common source lines CSL1 to CSLk. For example, the string select transistors SST of the cell strings CS11 to CS1n may be commonly connected to the common source line CSL1, and the string select transistors SST of the cell strings CSk1 to CSkn may be commonly connected to the common source line CSLk.

Memory cells MC located at the same height from the string select transistors SST may be commonly connected to one word line WL, and memory cells MC located at different heights may be connected to different word lines WL1 to WLn.

The circuit structure shown in FIG. 3 is only an example. For instance, the number of rows of the cell strings CS may be increased or decreased. As the number of rows of the cell strings CS varies, the number of string select lines SSL connected to the rows of the cell strings CS and the number of cell strings CS connected to each of the bit lines BL may also vary. As the number of rows of the cell strings CS varies, the number of common source lines CSL connected to the rows of the cell strings CS may also vary.

The number of columns of the cell strings CS may be increased or decreased. As the number of columns of the cell strings CS varies, the number of bit lines BL connected to the columns of the cell strings CS and the number of cell strings CS connected to each of the string select lines SSL may also vary.

The height of the cell strings CS may also be increased or decreased. For example, the number of memory cells MC stacked in each of the cell strings CS may be increased or decreased. As the number of memory cells MC stacked in each of the cell strings CS varies, the number of word lines WL may also vary. For example, the number of string select transistors SST provided in each of the cell strings CS may be increased. As the number of string select transistors SST provided in each of the cell strings CS varies, the number of string select lines SSL or the number of common source lines CSL may also vary. When the number of string select transistors SST increases, the string select transistors SST may be stacked in the same manner as the memory cells MC.

For example, programming and reading may be performed in units of rows of the cell strings CS. The cell strings CS may be selected in units of rows through the common source lines CSL. The cell stings CS may also be selected in units of rows through the string select lines SSL. In addition, voltage may be applied to the common source lines CSL in units of at least two common source lines CSL. Alternatively, voltage may be applied to all the common source lines CSL by treating all the common source lines CSL as a single unit.

In a selected row of the cell strings CS, programming and reading may be performed in units of pages. A page may refer to a row of memory cells connected to one word line WL. In a selected row of the cell strings CS, memory cells MC may be selected in units of pages by the word lines WL. For example, each of the gate electrodes 131 shown in FIG. 1 may be connected to one of the word lines WL and the string select lines SSL.

For example, when a memory cell MC targeted for programming is selected in a program mode, a turn-off voltage may be applied to a gate electrode 131 of the selected memory cell MC to limit and/or prevent channel formation, and a turn-on voltage (e.g., 0 V) may be applied to gate electrodes 131 of unselected memory cells MC to bring the unselected memory cells MC into a channel-on state. The turn-off voltage may be a positive voltage. As oxygen ions included in the oxide semiconductor layer 123 corresponding to the selected memory cell MC move to the oxygen reservoir layer 122, oxygen vacancies increase in the oxide semiconductor layer 123. In other words, as oxygen vacancies included in the oxygen reservoir layer 122 corresponding to the selected memory cell MC move into the oxide semiconductor layer 123, oxygen vacancies increase in the oxide semiconductor layer 123. When the density of oxygen vacancies in the oxide semiconductor layer 123 reaches or exceeds a first reference value, the energy band of the oxide semiconductor layer 123 reduces, thereby changing the electrical conductivity of the oxide semiconductor layer 123 and allowing data to be stored in the selected memory cell MC. Here, the first reference value refers to a reference value at which the electrical conductivity of an oxide semiconductor significantly decreases.

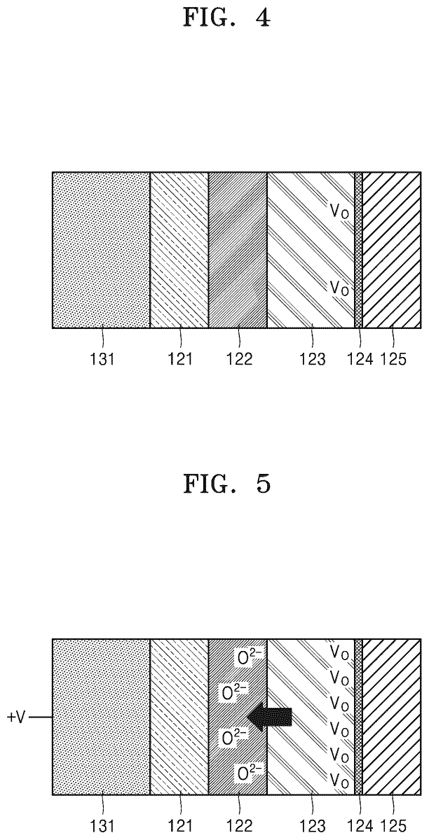

FIG. 4 is a view illustrating oxygen vacancies when no operation voltage is applied to a selected memory cell according to an embodiment, and FIG. 5 is a view illustrating oxygen ions and oxygen vacancies when a positive voltage is applied to the selected memory cell according to an embodiment.

As shown in FIG. 4, the memory cell included in an electrochemical memory device of an embodiment inherently includes oxygen vacancies Vo in an oxide semiconductor layer 123 due to an oxygen getter layer 124. When a positive voltage is applied to a gate electrode 131 as shown in FIG. 5, oxygen ions (O²⁻) included in the oxide semiconductor layer 123 move to an oxygen reservoir layer 122. Due to the movement of oxygen ions (O²⁻), oxygen vacancies Vo may increase in the oxide semiconductor layer 123. Because the oxide semiconductor layer 123 inherently includes oxygen vacancies Vo, the amount of oxygen vacancies Vo may be increased beyond a first reference value even with a small operation voltage. When the operation voltage is low, interference between memory cells may be reduced, and the integration density of memory cells may be increased. In an embodiment, a program voltage applied to the memory cell may be about 5 V or less, about 3 V or less, or greater than 0 V.

When a memory cell targeted for erasing is selected in an erase mode, a turn-off voltage may be applied to a gate electrode 131 of the selected memory cell to limit and/or prevent channel formation, and a turn-on voltage (e.g., 0 V) may be applied to gate electrodes 131 of unselected memory cells to bring the unselected memory cells into a channel-on state. The turn-off voltage may be a negative voltage. As oxygen ions (O²⁻) included in an oxygen reservoir layer 122 corresponding to the selected memory cell move to an oxide semiconductor layer 123, oxygen vacancies Vo decrease in the oxide semiconductor layer 123. In other words, as oxygen vacancies Vo included in the oxide semiconductor layer 123 corresponding to the selected memory cell move into the oxygen reservoir layer 122, oxygen vacancies decrease in the oxide semiconductor layer 123. When the density of oxygen vacancies Vo in the oxide semiconductor layer 123 reaches or exceeds a second reference value, the electrical conductivity of the oxide semiconductor layer 123 varies, and thus, data stored in the selected memory cell is erased. Here, the second reference value refers to a reference value at which the electrical conductivity of an oxide semiconductor significantly increases.

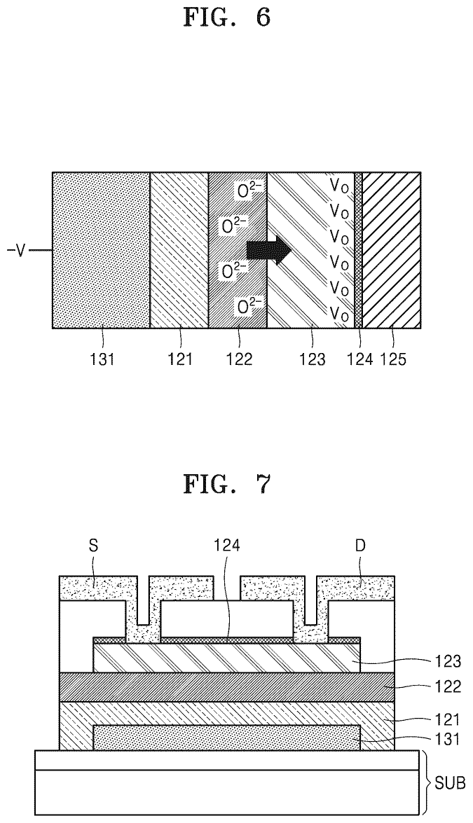

FIG. 6 is a view illustrating oxygen ions and oxygen vacancies when a negative voltage is applied to a selected memory cell according to an embodiment.

When a negative voltage is applied to a gate electrode 131 as shown in FIG. 6, oxygen ions (O²⁻) included in an oxygen reservoir layer 122 move into an oxide semiconductor layer 123. Due to the movement of oxygen ions (O²⁻), oxygen vacancies Vo may decrease in the oxide semiconductor layer 123. In an embodiment, an erase voltage applied to the memory cell may be about −12 V or greater, about −10 V or greater, about −7 V or greater, or less than 0 V.

FIG. 7 is a view illustrating a test memory device including an oxygen getter layer 124, according to an embodiment. A gate electrode 131, a gate insulating layer 121, an oxygen reservoir layer 122, an oxide semiconductor layer 123, and the oxygen getter layer 124 were sequentially formed on a substrate 101. Then, a source electrode S and a drain electrode D were formed on the oxide semiconductor layer 123. Tungsten (W) was used to form the gate electrode 131 to a thickness of 20 nm, aluminum oxide (Al₂O₃) was used to form the gate insulating layer 121 on the gate electrode 131 to a thickness of 10 nm, hafnium oxide (HfO₂) was used to form the oxygen reservoir layer 122 on the gate insulating layer 121 to a thickness of 10 nm, and indium gallium zinc oxide (IGZO) was used to form the oxide semiconductor layer 123 on the oxygen reservoir layer 122 to a thickness of 10 nm. Aluminum (Al) was used to form the oxygen getter layer 124 on the oxide semiconductor layer 123 to a thickness of 0.3 nm. Then, tungsten (W) was used to form the source electrode S and the drain electrode D apart from each other on the oxide semiconductor layer 123.

A memory device was prepared according to a comparative example by excluding the oxygen getter layer 124 from the memory devices shown in FIG. 7.

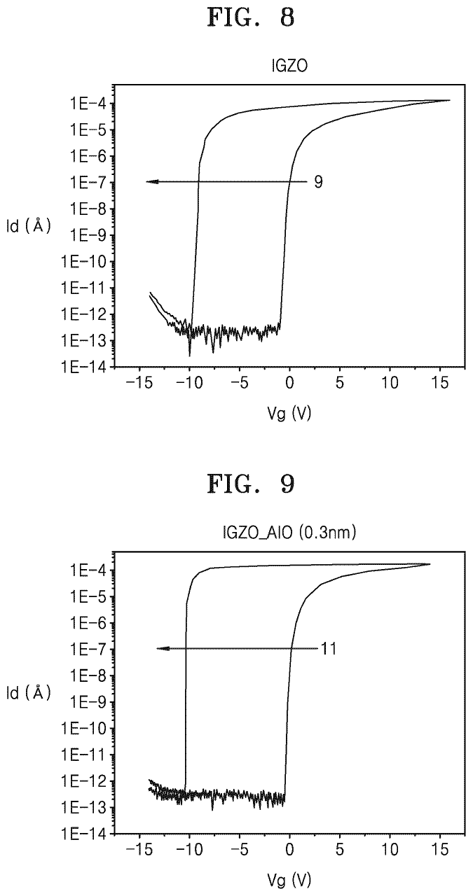

FIG. 8 is a graph illustrating current-voltage (IV) characteristics of the memory device of the comparative example. In the memory device of the comparative example, it may be confirmed that a gate voltage range in which hysteresis occurs is from about −10 V to about +10 V. In addition, a memory window of about 9 V may be confirmed.

FIG. 9 is a graph illustrating IV characteristics of the memory device of the embodiment. In the memory device of the embodiment, it may be confirmed that a gate voltage range in which hysteresis occurs is from about −9 V to about +2 V. In addition, a memory window of about 11 V may be confirmed.

It may be confirmed that a positive operation voltage for the memory device including the oxygen getter layer 124 is +2 V is significantly lower than a positive operation voltage of +10 V for the memory device of the comparative example not including the oxygen getter layer 124. The reason for this is that oxygen vacancies are inherently present in the oxide semiconductor layer 123 due to the oxygen getter layer 124. Although the operation voltage range of the memory device of the embodiment is reduced to 11 V compared with 20 V in the comparative example, the memory device of the embodiment has a larger memory window than the memory device of the comparative example. The operation voltage range of the memory cell of the embodiment may be about 15 V or less, about 12 V or less, or about 10 V or less.

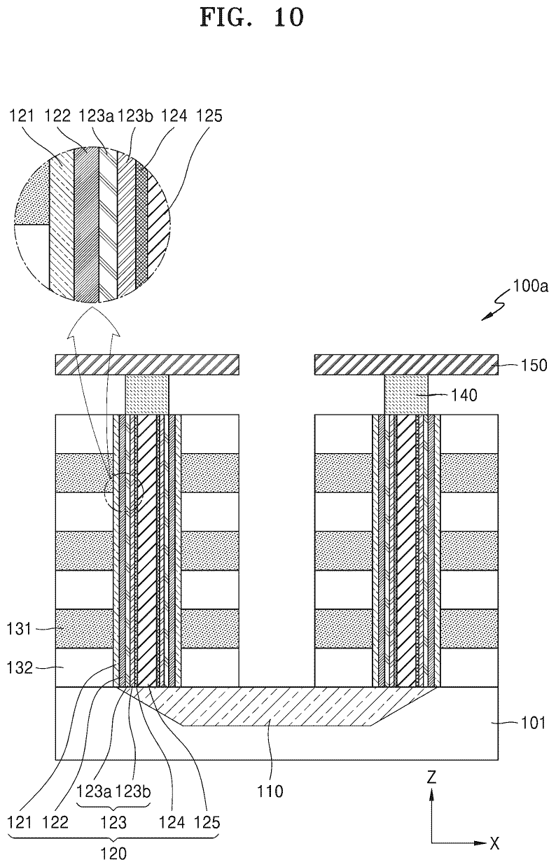

FIG. 10 is a view illustrating an electrochemical memory device 100a including a plurality of oxide semiconductor layers 123, according to an embodiment. Comparing FIGS. 1 and 10, the oxide semiconductor layers 123 shown in FIG. 10 may include a first oxide semiconductor layer 123a and a second oxide semiconductor layer 123b that have different oxygen dissociation energies. The first oxide semiconductor layer 123a and the second oxide semiconductor layer 123b may be sequentially arranged from an oxygen reservoir layer 122 toward an oxygen getter layer 124. The oxygen dissociation energy of the second oxide semiconductor layer 123b may be less than the oxygen dissociation energy of the first oxide semiconductor layer 123a.

When the oxygen getter layer 124 is formed, more oxygen vacancies may be generated in the second oxide semiconductor layer 123b than in the first oxide semiconductor layer 123a. Because the oxygen dissociation energy of the second oxide semiconductor layer 123b is less than the oxygen dissociation energy of the first oxide semiconductor layer 123a, when a positive voltage is applied to a gate electrode 131, oxygen ions may be more easily released from the second oxide semiconductor layer 123b than from the first oxide semiconductor layer 123a, resulting in more oxygen vacancies in the second oxide semiconductor layer 123b than in the first oxide semiconductor layer 123a. Because oxygen vacancies are concentrated in the second oxide semiconductor layer 123b, the electrical conductivity of the oxide semiconductor layers 123 may be more easily changed. Therefore, the electrochemical memory device 100a of the embodiment may operate within a relatively narrow operation voltage range.

The first oxide semiconductor layer 123a and the second oxide semiconductor layer 123b may differ from each other in at least one metal component. However, embodiments are not limited thereto. The first oxide semiconductor layer 123a and the second oxide semiconductor layer 123b may include the same metal, but have different contents of the metal, resulting in different oxygen dissociation energies. For example, when each of the first oxide semiconductor layer 123a and the second oxide semiconductor layer 123b includes indium (In), gallium (Ga), and zinc (Zn), gallium (Ga) has the highest oxygen dissociation energy, and indium (In) has the lowest oxygen dissociation energy. In this case, the first oxide semiconductor layer 123a may include more gallium (Ga) than the second oxide semiconductor layer 123b, and the second oxide semiconductor layer 123b may include more indium (In) than the first oxide semiconductor layer 123a. For example, the first oxide semiconductor layer 123a may include gallium (Ga) in an amount exceeding 33 at %, or the second oxide semiconductor layer 123 b may include indium (In) in an amount exceeding 33 at %.

Alternatively, in an embodiment, the second oxide semiconductor layer 123b may include a halogen element. For example, the halogen element may include at least one selected from fluorine (F), chlorine (Cl), bromine (Br), and iodine (I). For example, when the oxide semiconductor layers 123 include fluorine (F), the content of fluorine may be 2×10¹⁴/cm² or more. The halogen element may facilitate the movement of oxygen ions and may also ensure the thermal stability of the electrochemical memory device 100a.

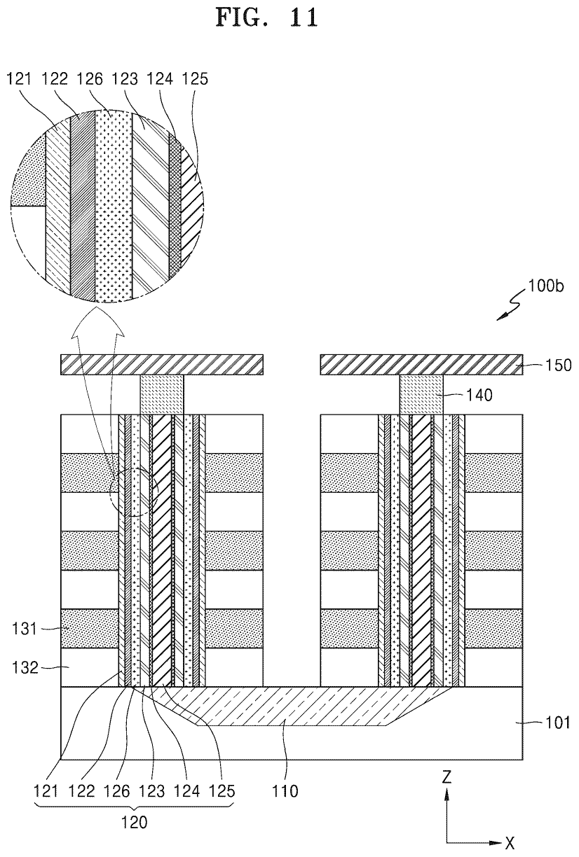

FIG. 11 is a view illustrating an electrochemical memory device 100b including an electrolyte layer 126, according to an embodiment. Comparing FIGS. 1 and 11, the electrochemical memory device 110b shown in FIG. 11 may further include an electrolyte layer 126 between an oxygen reservoir layer 122 and an oxide semiconductor layer 123.

Ions (cations and/or anions) included in the electrolyte layer 126 may be arranged in response to the polarity of voltage applied to a gate electrode 131, and thus, the movement of oxygen ions between the oxygen reservoir layer 122 and the oxide semiconductor layer 123 may be facilitated. For example, when a positive voltage is applied to the gate electrode 131, the electrolyte layer 126 may move oxygen ions included in the oxygen reservoir layer 122 into the oxide semiconductor layer 123, and when a negative voltage is applied to the gate electrode 131, the electrolyte layer 126 may move oxygen ions included in the oxide semiconductor layer 123 into the oxygen reservoir layer 122.

The oxygen dissociation energy of the electrolyte layer 126 may be less than the oxygen dissociation energy of the oxygen reservoir layer 122 and greater than the oxygen dissociation energy of the oxide semiconductor layer 123. The electrolyte layer 126 may include an insulative metal oxide. For example, the electrolyte layer 126 may include an oxide including at least one selected from tantalum (Ta), hafnium (Hf), aluminum (Al), zinc (Zn), tungsten (W), vanadium (V), titanium (Ti), niobium (Nb), germanium (Ge), arsenic (As), tellurium (Te), antimony (Sb), gallium (Ga), indium (In), zirconium (Zr), tin (Sn), and nickel (Ni), but is not limited thereto. In an example, the electrolyte layer 126 may include hafnium oxide.

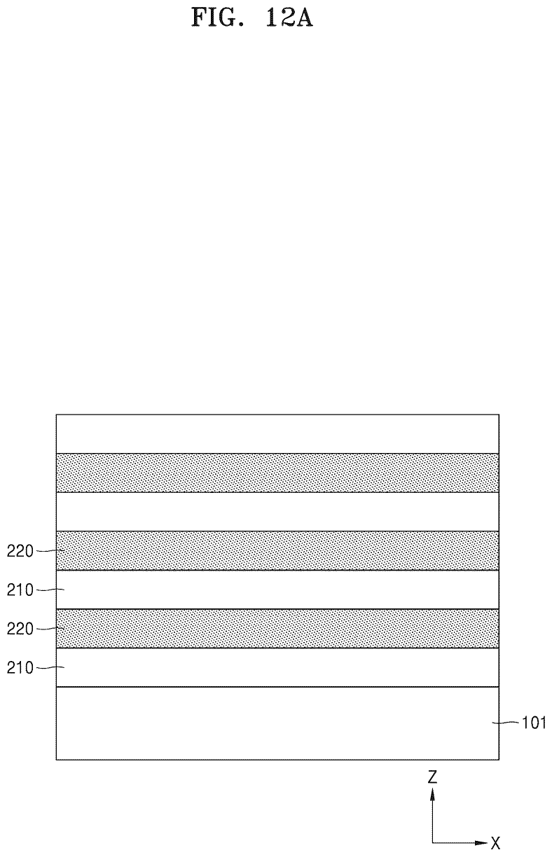

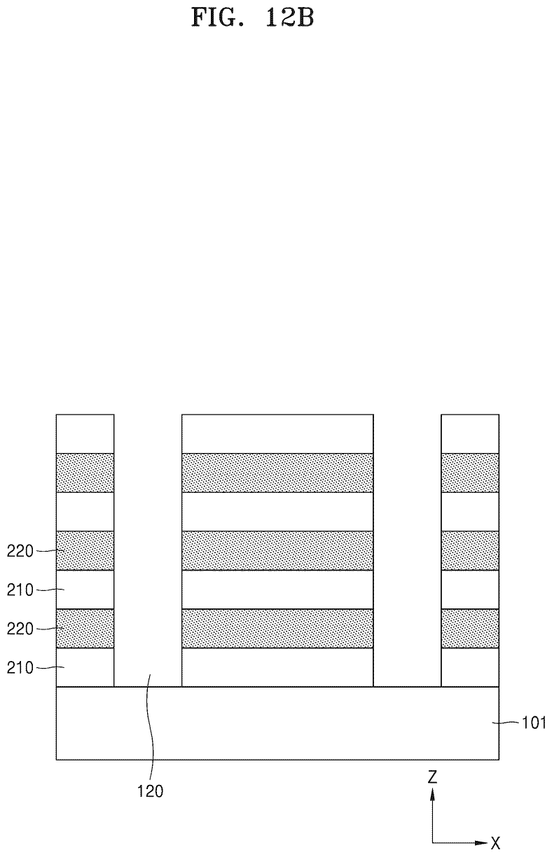

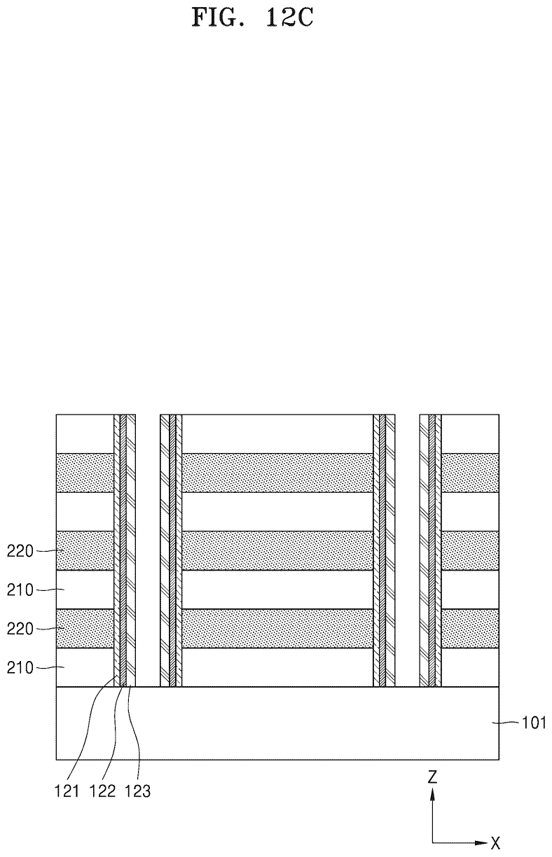

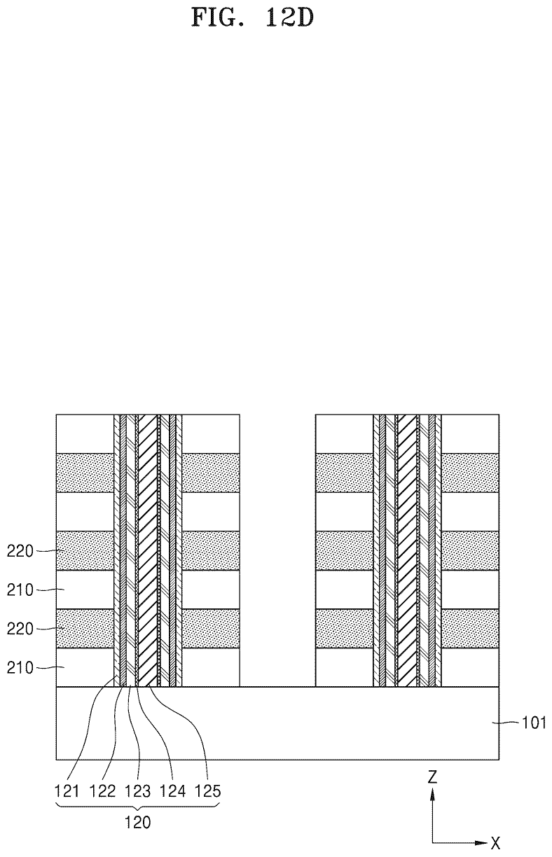

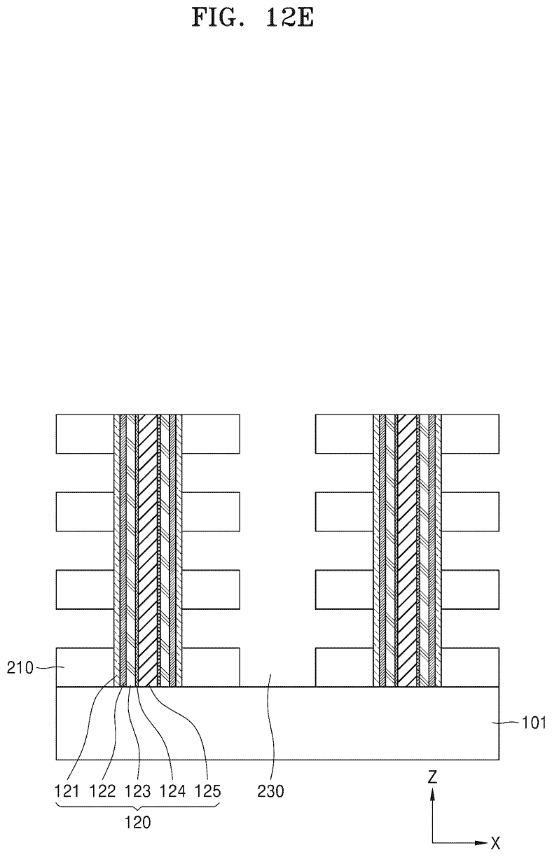

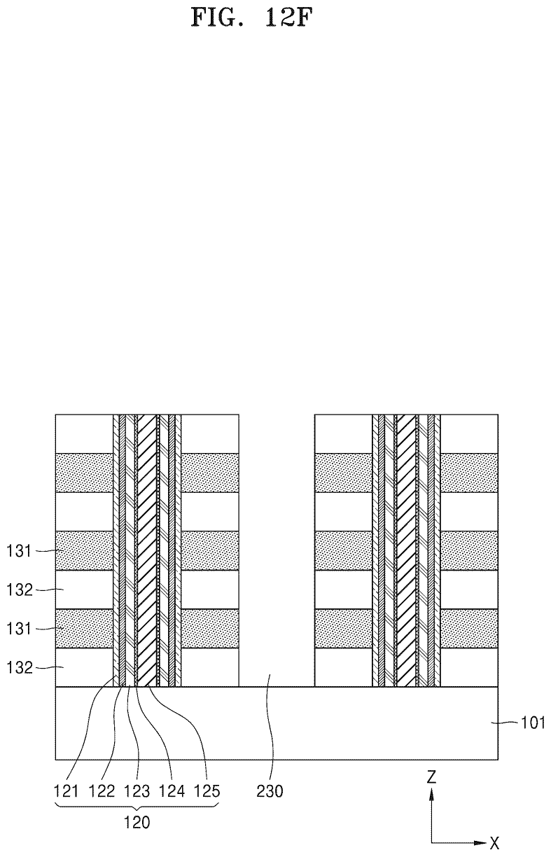

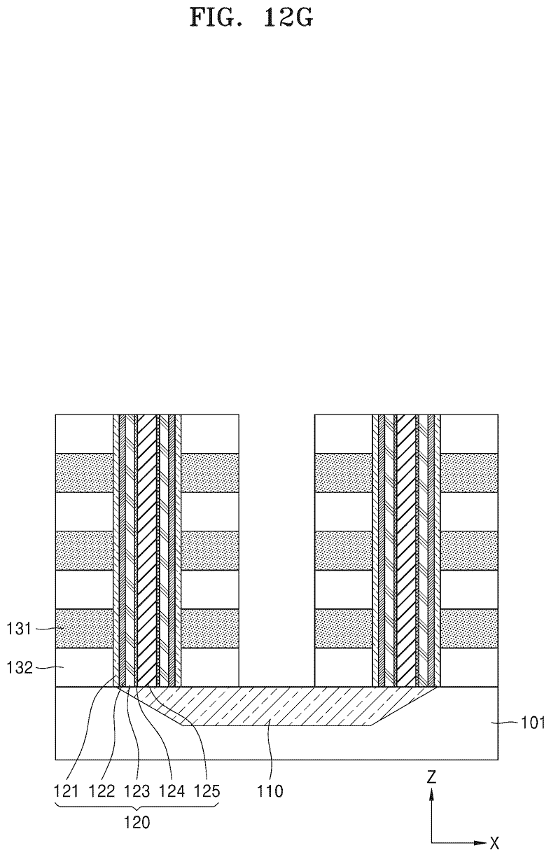

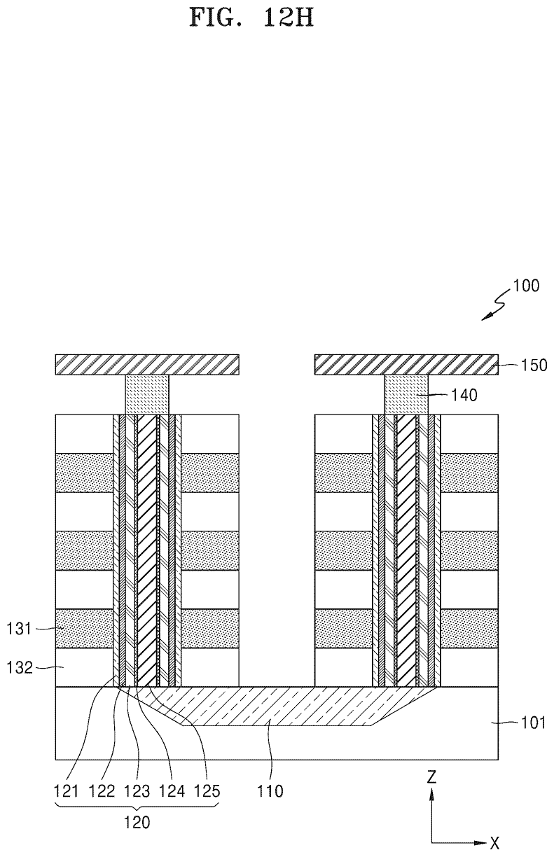

FIGS. 12A to 12H are reference views illustrating a method of manufacturing an electrochemical memory device 100 according to an embodiment.

Referring to FIG. 12A, first insulating material layers 210 and second insulating material layers 220 may be alternately stacked on a substrate 101. The first insulating material layers 210 and the second insulating material layers 220 may be alternately stacked in a direction perpendicular to a surface of the substrate 101. The first and second insulating material layers 210 and 220 may include different materials. The first and second insulating material layers 210 and 220 may include, for example, silicon oxide, silicon nitride, or the like, but are not limited thereto.

Referring to FIG. 12B, channel holes 120 are formed through the first and second insulating material layers 210 and 220. Here, the channel holes 120 may extend in the direction perpendicular to the surface of the substrate 101. The channel holes 120 may each have a circular cross-section. The channel holes 120 may be formed by anisotropically etching the first and second insulating material layers 210 and 220. The surface of the substrate 101 may be exposed through the channel holes 120. The channel holes 120 may be spaced apart from each other in a direction parallel to the surface (e.g., upper surface) of the substrate 101.

Referring to FIG. 12C, a gate insulating layer 121, an oxygen reservoir layer 122, and an oxide semiconductor layer 123 may be sequentially formed on an inner wall of each of the channel holes 120. The gate insulating layer 121 may extend in the direction perpendicular to the surface of the substrate 101. The gate insulating layer 121 may be formed on the inner wall of each of the channel holes 120 and may thus be in contact with the first and second insulating material layers 210 and 220.

The oxygen reservoir layer 122 may be in contact with an inner lateral surface of the gate insulating layer 121. The oxygen reservoir layer 122 may include a material that has lower oxygen dissociation energy than a material included in the gate insulating layer 121. The oxygen reservoir layer 122 may include a metal oxide that does not satisfy a stoichiometric ratio.

The oxide semiconductor layer 123 may be in contact with an inner lateral surface of the oxygen reservoir layer 122. The oxide semiconductor layer 123 may include a material that has lower oxygen dissociation energy than the material included in the oxygen reservoir layer 122.

Referring to FIG. 12D, an oxygen getter layer 124 may be formed on an inner wall of the oxide semiconductor layer 123. The oxygen getter layer 124 may include a metal that has lower oxide formation energy than a metal included in the oxide semiconductor layer 123. At least a portion of the metal, which is a source of the oxygen getter layer 124, may bond with oxygen included in the oxide semiconductor layer 123 when being adsorbed onto the oxide semiconductor layer 123. The oxygen getter layer 124 may be formed by acquiring oxygen from the oxide semiconductor layer 123, while oxygen vacancies may be generated in the oxide semiconductor layer 123 due to the release of oxygen. In other words, when the oxygen getter layer 124 is formed, the oxygen getter layer 124 may generate oxygen vacancies in the oxide semiconductor layer 123.

When the oxygen getter layer 124 is formed to be thicker, more oxygen vacancies may be generated in the oxide semiconductor layer 123. When excessive oxygen vacancies are generated in the oxide semiconductor layer 123, the oxide semiconductor layer 123 may lose semiconductor characteristics. Therefore, the oxygen getter layer 124 may have a thickness allowing the oxide semiconductor layer 123 to maintain semiconductor characteristics. For example, the oxygen getter layer 124 may have a thickness of about 1 nm or less, about 0.5 nm or less, or about 0.3 nm or less.

A pillar 125 may be additionally formed inside the oxygen getter layer 124. Although the formation of the pillar 125 is illustrated in FIG. 12D, embodiments are not limited thereto. The pillar 125 may be formed together with gate electrodes 131 (described later) when the gate electrodes 131 are formed.

Referring to FIG. 12E, an opening 230 may be formed through the first and second insulating material layers 210 and 220, and the second insulating material layers 220 may be removed to expose the gate insulating layer 121. The second insulating material layers 220 may be etched away through a wet etching process. Remaining portions of the first insulating material layers 210 may be spaced apart from each other in a vertical direction over the substrate 101 and may surround the gate insulating layer 121.

Referring to FIG. 12F, gate electrodes 131 may be formed in regions from which the second insulating material layers 220 have been removed. The pillar 125 may be formed together with the source electrodes when the gate electrodes 131 are formed. The remaining portions of the first insulating material layers 210 may become isolation layers 132. The pillar 125 may be formed during the formation of the gate electrodes 131.

Referring to FIG. 12G, a common source region 110 may be formed in an upper portion of the substrate 101 that is exposed through the opening 230. For example, the common source region 110 may be formed by doping with an n-type dopant such as phosphorus (P).

Referring to FIG. 12H, drains 140 may be formed above the oxygen reservoir layers 122, and bit lines 150 may be formed on the drains 140.

The electrochemical memory device 100 includes a plurality of memory cells that may be configured to retain information even when power is off, and thus, the information stored in the memory cells may be used when power is supplied. The electrochemical memory device 100 may be widely applied to cellular phones, digital cameras, personal digital assistants (PDAs), portable computing devices, and the like.

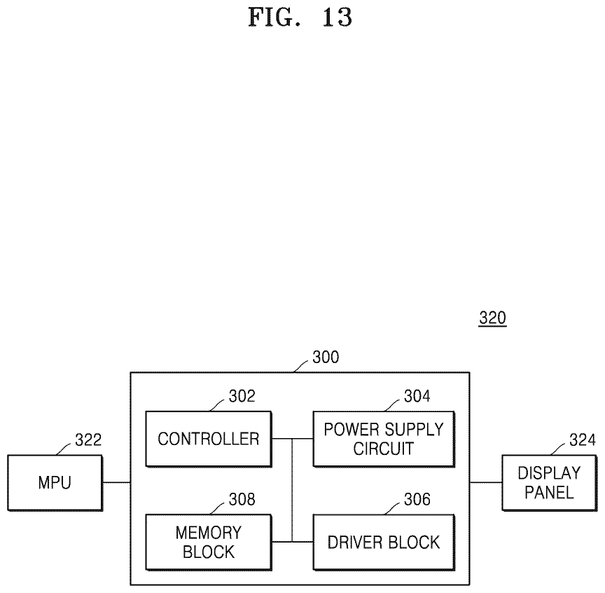

FIG. 13 is a block diagram schematically illustrating a display driver integrated circuit (display driver IC or DDI) 300 and a display apparatus 320 including the DDI 300, according to an embodiment. Referring to FIG. 13, the DDI 300 may include a controller 302, a power supply circuit 304, a driver block 306, and a memory block 308. The controller 302 may receive and decode instructions from a main processing unit (MPU) 322 and may control each block of the DDI 300 to implement operations according to the instructions. The power supply circuit 304 may generate drive voltage in response to control of the controller 302. The driver block 306 may drive a display panel 324 using the drive voltage that is generated by the power supply circuit 304 in response to the control of the controller 302. The display panel 324 may include, for example, a liquid crystal display (LCD) panel, an organic light-emitting device (OLED) display panel, or a plasma display panel (PDP). The memory block 308 may temporarily store instructions input to the controller 302 or control signals output from the controller 302, or may store necessary data. The memory block 308 may include memory such as random-access memory (RAM) or ROM. For example, the memory block 308 may include at least one of the electrochemical memory devices 100, 100a, and 100b described in the above embodiments.

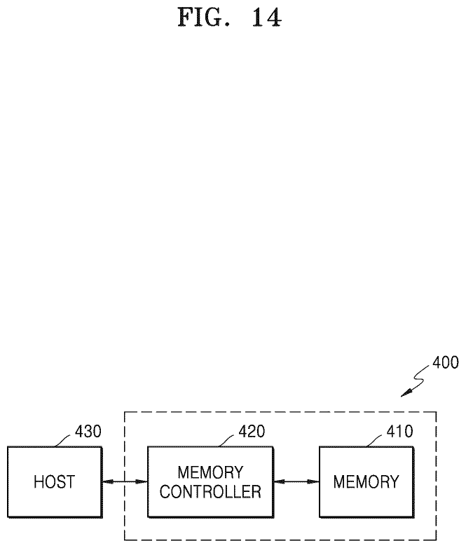

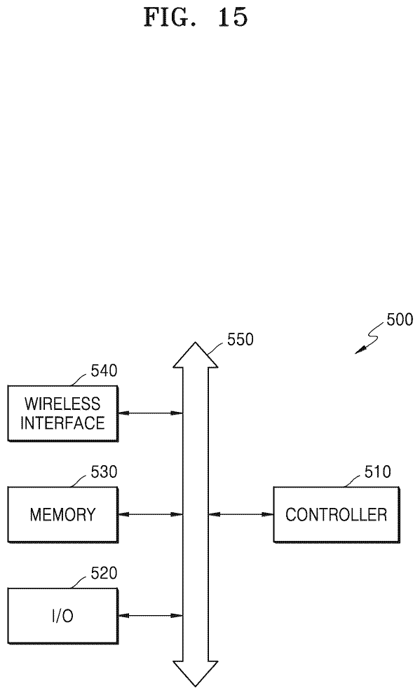

FIG. 14 is a block diagram illustrating an electronic device 400 according to an embodiment. Referring to FIG. 14, the electronic device 400 includes memory 410 and a memory controller 420. The memory controller 420 may control the memory 410 to read data from the memory 410 and/or program data to the memory 410 in response to requests from a host 430. The memory 410 may include at least one the electrochemical memory devices 100, 100a, and 100b described in the above embodiments.

FIG. 15 is a block diagram illustrating an electronic device 500 according to an embodiment. Referring to FIG. 15, the electronic device 500 may form a wireless communication device or a device capable of transmitting and/or receiving information in a wireless environment. The electronic device 500 includes a controller 510, an input/output (I/O) device 520, memory 530, and a wireless interface 540 that are connected to each other via a bus 550.

The controller 510 may include at least one selected from a microprocessor, a digital signal processor, and a similar processing device. The I/O device 520 may include at least one selected from a keypad, a keyboard, and a display. The memory 530 may store instructions executed by the controller 510. For example, the memory 530 may store user data. The electronic device 500 may use the wireless interface 540 to transmit/receive data over a wireless communication network. The wireless interface 540 may include an antenna and/or a wireless transceiver. In some embodiments, the electronic device 500 may utilize third-generation communication systems, for example, communication interface protocols of third-generation communication systems such as code division multiple access (CDMA), global system for mobile communications (GSM), North American digital cellular (NADC), extended time division multiple access (E-TDMA), and/or wide band code division multiple access (WCDMA). The memory 530 of the electronic device 500 may include at least one of the electrochemical memory devices 100, 100a, and 100b described in the above embodiments.

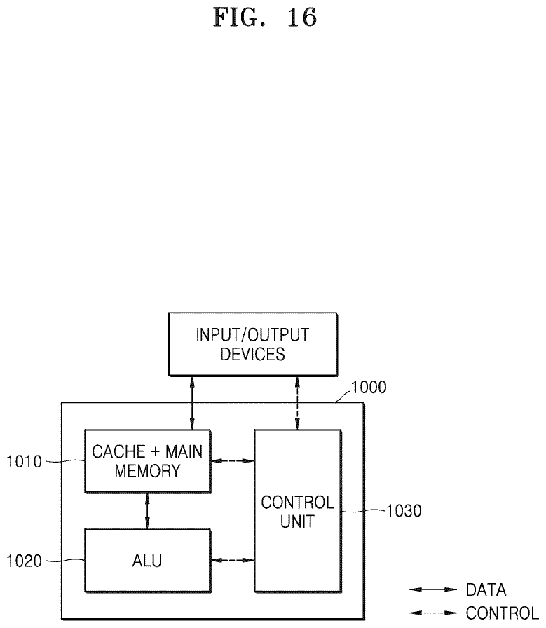

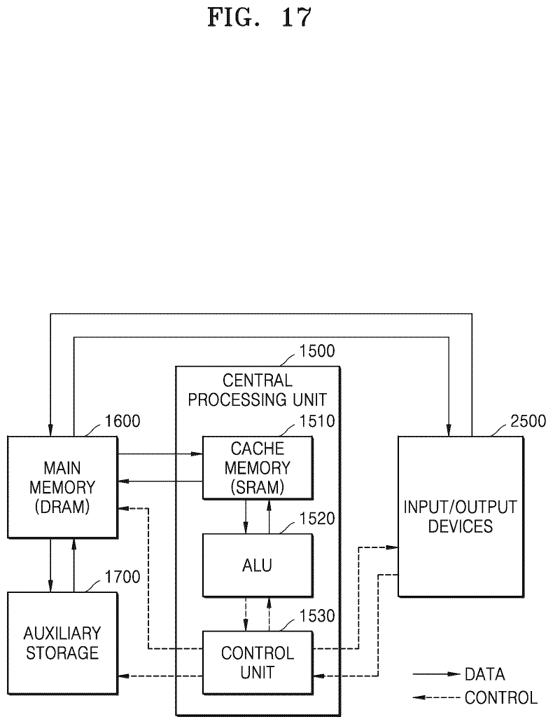

FIGS. 16 and 17 are conceptual views schematically illustrating device architectures applicable to electronic devices, according to embodiments.

Referring to FIG. 16, an electronic device architecture 1000 may include a memory unit 1010 and a control unit 1030. The electronic device architecture 1000 may further include an arithmetic logic unit (ALU) 1020. The memory unit 1010, the ALU 1020, and the control unit 1030 may be electrically connected to each other. For example, the electronic device architecture 1000 may be implemented as a single chip including the memory unit 1010, the ALU 1020, and the control unit 1030. For example, the memory unit 1010, the ALU 1020, and the control unit 1030 may be connected to each other on a chip through metal lines and may directly communicate with each other. The memory unit 1010, the ALU 1020, and the control unit 1030 may be monolithically integrated on a single substrate to form a single chip. Input/output devices may be connected to the electronic device architecture (chip) 1000. The memory unit 1010 may include main memory and cache memory. The electronic device architecture (chip) 1000 may serve as an on-chip memory processing unit. The memory unit 1010, the ALU 1020, and/or the control unit 1030 may independently include at least one of the electrochemical memory devices 100, 100a, and 100b described in the above embodiments.

Referring to FIG. 17, cache memory 1510, an ALU 1520, and a control unit 1530 may form a central processing unit (CPU) 1500, and the cache memory 1510 may include static random-access memory (SRAM). In addition to the CPU 1500, main memory 1600 and auxiliary storage 1700 may be provided, and an input/output device 2500 may be provided. For example, the main memory 1600 may be dynamic random-access memory (DRAM) and may include at least one of the electrochemical memory devices 100, 100a, and 100b described in the above embodiments. The auxiliary storage 1700 may include at least one of the electrochemical memory devices 100, 100a, and 100b described in the above embodiments.

In some cases, an electronic device architecture may be implemented as a single chip on which computing unit devices and memory unit devices are adjacent to each other without distinguishing between sub-units.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An electrochemical memory device comprising:
a substrate;
a plurality of isolation layers and a plurality of gate electrodes alternately stacked in a first direction on a surface of the substrate, the first direction being perpendicular to the surface of the substrate, the plurality of isolation layers and the plurality of gate electrodes defining a channel hole penetrating the plurality of isolation layers and the plurality of gate electrodes in the first direction;
an oxygen reservoir layer in the channel hole and configured to store at least one of oxygen ions and oxygen vacancies;
an oxide semiconductor layer on an inner side of the oxygen reservoir layer; and
an oxygen getter layer on an inner side of the oxide semiconductor layer and configured to generate oxygen vacancies in the oxide semiconductor layer.

2. The electrochemical memory device of claim 1, wherein the oxygen getter layer is insulative.

3. The electrochemical memory device of claim 1, wherein
the oxygen getter layer comprises a first metal,
the oxide semiconductor layer comprises a second metal that is different from the first metal, and
the first metal has a lower oxide formation energy than the second metal.

4. The electrochemical memory device of claim 3, wherein
the oxide semiconductor layer comprises the first metal, and
a content of the first metal in the oxygen getter layer is greater than a content of the first metal in the oxide semiconductor layer.

5. The electrochemical memory device of claim 3, wherein a content of the first metal included in the oxide semiconductor layer decreases from a region in contact with the oxygen getter layer to a region in contact with the oxygen reservoir layer.

6. The electrochemical memory device of claim 3, wherein a content of the first metal in the oxide semiconductor layer is less than a content of the second metal in the oxide semiconductor layer.

7. The electrochemical memory device of claim 3, wherein a content of the second metal in the oxygen getter layer is 0 at %.

8. The electrochemical memory device of claim 1, wherein the oxygen getter layer comprises a metal having an oxide formation energy of −900 kJ/mol or less at a pressure of 1 atm and a temperature of 0 °C to 400 °C.

9. The electrochemical memory device of claim 1, wherein the oxygen getter layer comprises at least one selected from aluminum (Al), magnesium (Mg), and calcium (Ca).

10. The electrochemical memory device of claim 1, wherein the oxygen getter layer has a thickness of 1 nm or less.

11. The electrochemical memory device of claim 1, wherein the oxide semiconductor layer comprises an oxide comprising at least one selected from indium (In), gallium (Ga), tin (Sn), cadmium (Cd), germanium (Ge), hafnium (Hf), and zinc (Zn).

12. The electrochemical memory device of claim 1, wherein the oxygen reservoir layer comprises a metal oxide that does not satisfy a stoichiometric ratio.

13. The electrochemical memory device of claim 11, wherein the oxygen reservoir layer comprises at least one selected from molybdenum (Mo), gadolinium (Gd), tantalum (Ta), hafnium (Hf), aluminum (Al), zinc (Zn), tungsten (W), vanadium (V), titanium (Ti), niobium (Nb), germanium (Ge), arsenic (As), tellurium (Te), antimony (Sb), gallium (Ga), indium (In), zirconium (Zr), tin (Sn), and nickel (Ni).

14. The electrochemical memory device of claim 1, wherein the oxide semiconductor layer comprises:
a first oxide semiconductor layer between the oxygen reservoir layer and the oxygen getter layer and having a lower oxygen dissociation energy than the oxygen reservoir layer; and
a second oxide semiconductor layer between the first oxide semiconductor layer and the oxygen getter layer and having a lower oxygen dissociation energy than the first oxide semiconductor layer.

15. The electrochemical memory device of claim 1, further comprising:
an electrolyte layer between the oxygen reservoir layer and the oxide semiconductor layer.

16. The electrochemical memory device of claim 1, further comprising:
a gate insulating layer between the oxygen reservoir layer and the plurality of gate electrodes.

17. The electrochemical memory device of claim 1, wherein the oxide semiconductor layer is doped with a halogen element.

18. An electronic device comprising:
a nonvolatile memory device; and
a memory controller configured to control the nonvolatile memory device, the memory controller being configured to read data from the nonvolatile memory device and/or program data to the nonvolatile memory device,
wherein the nonvolatile memory device comprises
a substrate,
a plurality of isolation layers and a plurality of gate electrodes alternately stacked in a first direction on a surface of the substrate, the first direction being perpendicular to the surface of the substrate, the plurality of isolation layers and the plurality of gate electrodes defining a channel hole penetrating the plurality of isolation layers and the plurality of gate electrodes in the first direction,
an oxygen reservoir layer in the channel hole and configured to store at least one of oxygen ions and oxygen vacancies,
an oxide semiconductor layer on an inner side of the oxygen reservoir layer, and
an oxygen getter layer on an inner side of the oxide semiconductor layer and configured to generate oxygen vacancies in the oxide semiconductor layer.

19. A method of manufacturing an electrochemical memory device, the method comprising:
alternately forming a plurality of first insulating material layers and a plurality of second insulating material layers on a substrate;
forming a channel hole that penetrates the plurality of first insulating material layers and the plurality of second insulating material layers in a first direction, the first direction being perpendicular to the substrate;
sequentially forming an oxygen reservoir layer and an oxide semiconductor layer on an inner side of the channel hole; and
forming an oxygen getter layer on an inner side of the oxide semiconductor layer by using oxygen included in the oxide semiconductor layer.

20. The method of claim 19, wherein the oxygen getter layer comprises at least one selected from aluminum (Al), magnesium (Mg), and calcium (Ca).
